(19) United States
(12) Patent Application Publication
(10) Pub. No.: US 2015/0002204 A1
(43) Pub. Date: Jan. 1, 2015

(54) VARIABLE IMPEDANCE DRIVER FOR RESONANT CLOCK NETWORKS

(71) Applicant: International Business Machines Corporation, Armonk, NY (US)

(72) Inventors: Anthony G. Aipperspach, Rochester, MN (US); Roger J. Gravrok, Eau Claire, WI (US); Mark G. Veldhuizen, Rochester, MN (US)

(21) Appl. No.: 13/931,087

(22) Filed: Jun. 28, 2013

(51) Int. Cl. H03K 5/145

(52) U.S. Cl. CPC H03K 5/145
USPC 327/299

(57) ABSTRACT

An IC is disclosed which includes multiple sectors, each having a resonant clock distribution structure and a sector clock buffer. The sector clock buffer can drive a clock signal onto the resonant clock distribution structure, in response to received clock signal and control signals. The sector clock buffer includes a first driver circuit, with a first impedance to drive the clock signal during a first portion of first and second clock phases. The first driver circuit may cause oscillation of the resonant clock distribution structure. The sector clock buffer includes a second driver circuit, having a second impedance higher than the first impedance. The second driver circuit may maintain the clock signal during a second portion of the first and second clock phases, in response to the control signal. The second driver circuit may maintain the resonant clock distribution structure at one of two voltages.

### TECHNICAL FIELD

The present disclosure relates to integrated circuit (IC) clock signals. In particular, this disclosure relates to driving clock signals on resonant IC networks using a variable impedance driver.

### BACKGROUND

A clock signal is a particular type of signal that oscillates between a high and a low logic state, and may be used to coordinate the actions of elements of an integrated circuit (IC). Clocks may be used to synchronize the transfer of data between a number of latches, flip-flops, or other synchronous elements on an IC.

A clock signal may be produced by a clock generator, such as an oscillator or phase-locked loop (PLL). A distribution network may be required to supply the clock signal to the synchronous elements. The network may include a combination of tree structures and grid structures, and may also include repowering elements to increase the drive capability of the network. The distribution network may be designed to resonate in response to driving circuits.

### SUMMARY

Embodiments are directed towards a system including an integrated circuit (IC). The IC may have a plurality of sectors, with each sector having a resonant clock distribution structure, and at least one sector clock buffer. The sector clock buffer may be configured to receive a reference clock signal and a control signal, and to drive a clock signal onto the resonant clock distribution structure of the sector, in response to the reference clock signal. The sector clock buffer may have a first driver circuit, with a first impedance and configured to drive the clock signal during a first portion of a first clock signal phase, and during a first portion of a second clock signal phase. The first driver circuit may be configured to cause resonant oscillation of the resonant clock distribution structure.

The sector clock buffer may also have a second driver circuit, having a second impedance higher than the first impedance. The second driver circuit may be configured to maintain the clock signal during a second portion of the first clock signal phase, and during a second portion of the second clock signal phase, in response to the control signal. The second driver circuit may be configured to maintain the resonant clock distribution structure at one of a first and a second voltage.

Aspects of the various embodiments may allow a resonant clock distribution structure of an IC to be driven in a mode suitable to low frequency or DC testing of the IC. Aspects of the various embodiments may also be particularly useful for energy-efficient distribution of clock signals over a resonant network on an IC.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of embodiments of the disclosure and do not limit the invention.

FIG. 1 is a block diagram representation of integrated circuit (IC) including sectors and a sector clock buffer, according to embodiments of the present disclosure.

FIG. 2 is a block diagram representation of a sector of an IC including a sector clock buffer and a resonant clock distribution structure, according to embodiments.

FIG. 3 is a schematic representation of a sector clock buffer including low impedance and high impedance driver circuits, according to embodiments.

FIG. 4 is a diagram of resonant mode waveforms including sector clock buffer inputs and clock output, according to embodiments.

FIG. 5 is a diagram of dual driver mode waveforms including sector clock buffer inputs and clock output, according to embodiments.

FIG. 6 a diagram of DC test mode waveforms including sector clock buffer inputs and clock output, according to embodiments.

In the drawings and the Detailed Description, like numbers generally refer to like components, parts, steps, and processes. Reference numbers differing only by the addition of suffix letter may be used to indicate a signal or waveform associated with an electrical net or wire. For example, 409 may indicate a wire within a circuit, while 409A may indicate a signal waveform found on wire 409.

### DETAILED DESCRIPTION

The simultaneous trends of larger die sizes, an increasing number of clocked elements and higher clock frequencies of integrated circuits (ICs) have highlighted the need for energy-efficient IC clock distribution structures with low clock skew characteristics.

Clock grid structures are particularly useful for distribution of clocks on large, high-frequency ICs, due to their low clock skew, and low electrical resistance. Due to their size, clock grid structures may present a high capacitive load to clock drivers. Driving large, high-fanout clock grids with traditional push-pull clock circuits may require substantial amounts of power, and may consume a large portion of a chip's power budget.

A resonant clock grid structure may be suitable for distributing clock signals to clocked elements of an IC, and may consume less power than a non-resonant clock grid. Driving a resonant clock grid structure with impulse drivers may be an energy-efficient way to distribute clock signals on an IC.

While an impulse driver may be suitable for driving a resonant clock distribution structure at a specified operating clock frequency, it may not allow for driving of the resonant clock distribution structure at a lower frequency, which may be required for DC testing, or chip debug.

In general, various embodiments of the present disclosure relate to sector clock buffers that are designed to drive resonant clock structures of an IC using multiple impedances, and thereby enable resonant clock structures to be driven or held to specified voltage levels during low-frequency or DC testing of the IC.

Certain embodiments can be particularly useful by using impulse drivers to drive a resonant clock distribution networks, thereby reducing or eliminating driver shoot-through current and recycling charge injected into resonant clock networks, which may conserve energy, enabling IC's power budgets and specifications to be met.

The local distribution of impulse driver FET gate signals may be particularly useful in reducing clock skew and jitter, and eliminating the need for distribution of multiple narrow or high frequency control pulses to sector clock buffers.

An IC designed according to embodiments of the present disclosure may also be configured to distribute clock signals with reduced or eliminated overshoot, through the selection of the drive impulse width and the clock driver impedance. The energy injected into the resonant clock network may be controlled and the reliability of the IC increased.

Certain embodiments of the present disclosure can be appreciated in the context of driving a resonant clock distribution structure of an IC in one of multiple modes, using a variable impedance driver. Such driving modes may include a resonant mode, a dual-driver mode, and a DC test mode. While not necessarily limited thereto, embodiments discussed in this context can facilitate an understanding of various aspects of the disclosure. Certain embodiments may also be directed towards other associated applications, such a disabled clock mode. It is understood that some embodiments may not include all modes of operation, or the logical and/or circuit elements necessary to support all operation modes.

While all figures illustrate the principles and features of the present disclosure, they are not necessarily drawn to scale.

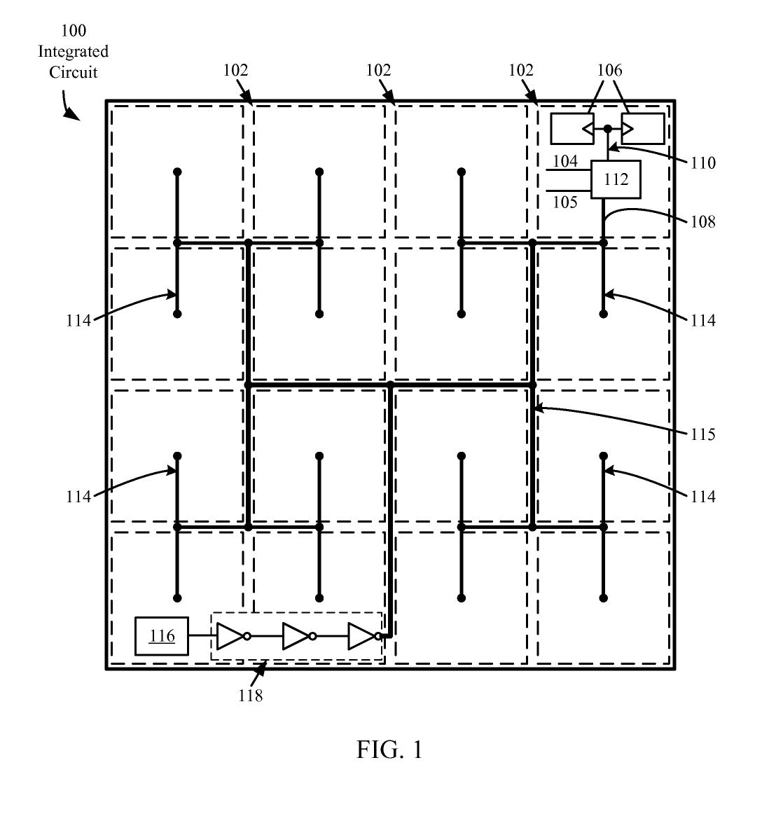

FIG. 1 is a block diagram illustrating an integrated circuit (IC) 100 divided into a plurality of sectors 102, and that includes clock source 116, clock repowering circuit 118, H-tree network 115 and H-tree sub-networks 114, according to embodiments of the present disclosure.

Each sector 102 contains at least one clocked element 106, and at least one sector clock buffer 112 having a clock signal input 108, a control input 104, a clock control input 105, and a clock signal output 110.

Clock source 116 may generate a reference clock signal that is received and repowered by clock buffer circuit 118, and then propagates across H-tree network 115, and H-tree sub-networks 114. The reference clock signal is received by sector clock buffer 112 on clock signal input 108, which is coupled to H-tree sub-network 114.

Sector clock buffer 112 may generate an output clock signal on clock signal output 110 in response to the received reference clock signal, control input 104 and clock control input 105. Clock signal output 110 may be connected to the clock inputs of clocked elements 106.

An IC 100 may be partitioned into a number of sectors 102, with each sector boundary depicting an area containing clocked elements 106 that are clocked by one or more neighboring sector clock buffers 112 located within the sector 102. The sector characteristics (shape, size, area, quantity, and arrangement) may be determined and specified by a designer so that certain IC 100 performance goals (e.g., clock skew or power budget) can be met. A designer may consider factors such as clocked element 106 density in a particular region of an IC 100, and the maximum drive capability of sector clock buffers 112, when specifying sector characteristics.

16 square-shaped sectors 102 are depicted in FIG. 1, however embodiments may include sectors having square, rectangular, or other regular or irregular shapes.

The clock source 116 may be a circuit such as an oscillator or phase-locked loop (PLL) that generates a regularly oscillating signal of a frequency suitable for clocking of the IC's synchronous elements, and may be fabricated as part of the IC, or may be external to the IC. The clock source 116 may be synchronized with an external clock input to the IC, which may have a lower frequency than the clock source 116. The clock repowering circuit 118 may comprise multiple stages of buffer circuits designed to adequately drive the H-tree network 115 with the reference clock signal from clock source 116.

Certain embodiments may include an H-tree network 115 and H-tree sub-networks 114, designed to distribute a reference clock signal from a clock repowering circuit 118 to the inputs of a plurality of sector clock buffers 112. Embodiments employing other clock distribution structures and topologies are possible.

A clock input network employing an H-tree network 115 and H-tree sub-networks 114 may be particularly useful in providing a balanced distribution structure, while providing low clock skew between inputs of sector clock buffers 112. Two levels of H-tree clock distribution (115, 114) are depicted in FIG. 1, however any suitable number of levels may be employed, and may serve to limit clock skew on the IC. Repowering buffers may be used between H-tree levels as needed to increase fanout drive capability of the network.

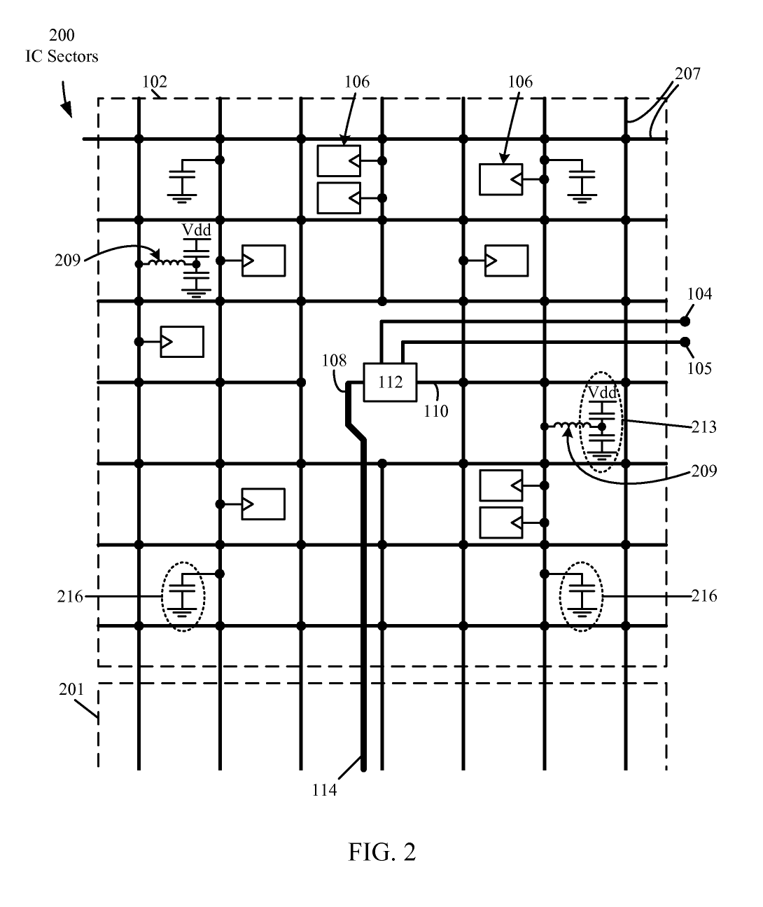

FIG. 2 is a block diagram representation of IC sectors 200, including sector 102 and adjacent sector 201. Sector 102 includes a clock grid 207, at least one clocked element 106, at least one sector clock buffer 112, AC coupling circuits 213 and inductors 209, in an embodiment consistent with FIG. 1. Clock grid 207 is a similar but extended implementation of clock signal output 110. Sector clock buffer 112 includes control input 104, clock control input 105, reference clock signal input 108 and clock signal output 110, according to embodiments. Capacitors 216 represent the capacitance of clock grid 207.

H-tree sub-network 114 may propagate a reference clock signal that is then received by reference clock signal input 108 of sector clock buffer 112. Sector clock buffer 112 may generate an output clock signal on clock signal output 110 in response to the received reference clock signal, control input 104 and clock control input 105. The output clock signal on clock signal output 110 may be used to drive to clock grid 207, which may resonate and supply a clock signal to the clocked elements 106 within sector 102.

Sector clock buffer 112 may generate a clock output signal on clock signal output 110 in response to the received reference clock signal, control input 104 and clock control input 105. Clock signal output 110 may be connected to the clock inputs of clocked elements 106.

Control input 104 and clock control input 105 may be shared with similar control inputs corresponding to other sectors 102 on the IC 100 (FIG. 1). These control signals may be operated at a frequency substantially less than the resonant clock frequency, and may not require high-speed nets.

The number of clock elements 106 within a particular sector 102 may be larger or smaller than the number of clock elements 106 within a particular adjacent sector 201, depending on the type and function of circuitry found within each sector 102, 201. Accordingly, each sector 102 may have a unique amount of capacitive loading coupled to clock grid 207.

Similarly, the number of sector clock buffers 112 within any particular sector 102 may vary depending on aggregate capacitive loading of the clock grid 207 and clocked elements 106. One sector clock buffer 112 per sector 102 is depicted in FIG. 2, however embodiments may include more than one sector clock buffer 112 per sector 102.

Clock grid 207 is depicted as a structure having regularly spaced horizontal and vertical IC conductor segments; however in some embodiments it may either have a regular or irregular structure. A designer may specify the number, dimensions and spacing of conductor segments and the use of IC conductor layers for the clock grid 207, in order to ensure that it has suitable skew, loading, and other performance characteristics.

Clock grid 207 is depicted having segments in sector 102 that connects to another clock grid 207 in adjacent sector 201. Embodiments may contain sectors 102 having a clock grid 207 that connects to one or more similar clock grids 207 of adjacent sectors 201, on one or more sides of sector 102. Embodiments of IC 100 (FIG. 1) may have the clock grid 207 of every sector 102 electrically connected to the clock grid 207 of every adjacent sector 201.

Clocked elements 106 may include latches, flip-flops, or other synchronous data storage circuit elements that make use of a clock signal to synchronize the capture and/or distribution of data.

Inductors 209 may be formed from IC metal layers in the grid, and may be of a spiral shape. Inductors may be electrically coupled between clock grid 207 and an AC coupling circuit 213. At least one inductor 209 may be present in each sector 102 to enable clock grid 207 to oscillate in a resonant mode. AC coupling circuit 213 may serve as a virtual ground for inductors 209, providing a path for charge injected into the clock grid 207 to be recycled.

Without the presence of inductors 209, clock grid 207 may exhibit primarily capacitive characteristics, due to the capacitive loading of clocked elements 106. A designer may specify the design of inductors 209 into clock grid 207, in order to increase its resonant characteristics, causing it to be a resonant clock distribution structure, a form of an LC tank circuit.

The resonant frequency of grid 207 may generally be described by the following equation:

$$f = \frac{1}{2 π \sqrt{LC}}$$

Where f=frequency in Hz
L is inductance in henries
C is capacitance in farads

A designer may specify an inductor with a particular inductance value to be designed into the clock grid 207. In one embodiment, for example, a sector clock buffer 112 drives 3 pF of capacitive loading, and has a corresponding 0.338 nH inductor in order to resonate at a specified frequency of approximately 5 GHz. Adjacent sectors 201 may have different capacitive loading values, and therefore require different inductor 209 values. Inductor 209 values may be independently determined and specified for multiple sectors 102 of the IC 100 (FIG. 1) to provide a consistent resonant frequency for all sectors 102.

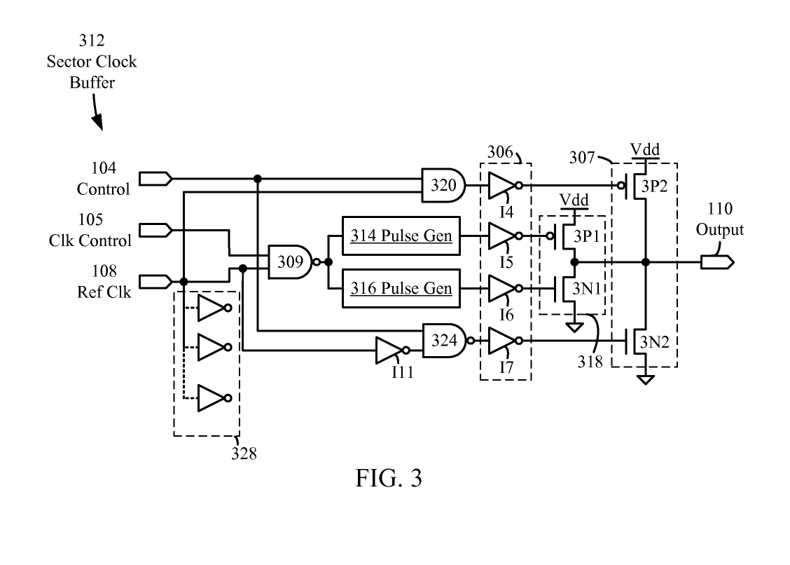

FIG. 3 is a schematic representation of a sector clock buffer 312 which receives input from control input 104, clock control input 105 and reference clock signal input 108, and drives a clock signal on clock signal output 110. Sector clock buffer 312 represents an embodiment of the function of sector clock buffer 112.

Sector clock buffer 312 comprises low impedance driver circuit 318, high impedance driver circuit 307, FET driving inverters 306, pulse generators 314, 316, variable input loading 328, NAND gates 309, 324, AND gate 320 and inverter I11, according to embodiments.

Low impedance driver circuit 318 comprises PFET 3P1, and NFET 3N1, configured to drive a clock signal output 110 with impulses to cause resonance of an attached resonant clock distribution structure (FIG. 2, 207). The impedance of PFET 3P1, and NFET 3N1 space may be 10 Ohms in embodiments.

High impedance driver circuit 307 comprises PFET 3P2, and NFET 3N2, configured to draw or hold a clock signal output 110 and an attached resonant clock distribution structure (FIG. 2, 207) to one of two voltage levels. The impedance of PFET 3P2, and NFET 3N2 may be 50 Ohms in one embodiment.

FET driving inverters 306 comprises inverters I4, I5, I6 and I7, configured to buffer received logic signals, and to drive FETs 3P2, 3P1, 3N1, and 3N2, respectively.

Variable input loading 328 comprises one or more load devices, configurable to provide a range of capacitive loading on reference clock signal input 108, which may enable a designer to balance the loading on an IC's clock distribution structure coupled to reference clock signal input 108. This may be particularly useful in balancing reference clock distribution structures that supply sectors having widely varying numbers of sector clock buffers 112. The load devices may include but are not limited to the inputs of logic gates, inverters and buffers.

Pulse generators 314, 316 are configured to supply pulses of a timing and duration to activate low impedance driver circuit 318. These pulses may occur during time periods synchronized with the clock phases of a signal on an attached resonant clock distribution structure.

The delay (from the triggering edges of the reference clock input) and pulse widths of pulses generated by pulse generators 314, 316 may be individually configured to be compatible with specific design parameters. Specified design parameters may include output resonant clock frequency, a maximum clock signal amplitude, and the energy needed to sustain resonance of clock grid 207 (FIG. 2).

Sector clock buffer 312 may be operated in any one of four different modes, according to the logic states of control input 104 and clock control input 105, as listed in Table 1. The modes include resonant mode, dual driver mode, DC test mode, and disabled mode.

Resonant mode may be used for driving a resonant clock signal with impulses from low-impedance FET drivers. Resonant mode may be used for driving clocks at a high frequency for IC functional operation.

The timing and duration of the drive impulses may be designed to add energy in a manner complimentary to the phases of the resonant clock signal. Impulses applied to a resonant clock signal may be designed to last for a portion of a particular clock phase. Contention between the sector clock buffer 312 and the resonant clock signal may be avoided. Shoot-through current in the sector clock buffer 312 may also be avoided, as only one FET device may be enabled at a time.

While operating in resonant mode, control input 104 is held to a logic 0, while clock control input 105 is held at a logic 1. The logic 1 on clock control input 105 causes NAND gate 309 to pass the complement of a signal on reference clock signal input 108 to both pulse generators 314, 316.

In response to a rising edge of a reference clock signal input, pulse generator 314, in conjunction with inverter I5 generates a negative pulse at the gate input of low impedance PFET 3P1, enabling it to pull up clock signal output 110.

Also in response to a falling edge of the reference clock signal input, pulse generator 316, in conjunction with inverter I6 generates a positive pulse at the gate input of low impedance NFET 3N1, enabling it to pull down clock signal output 110.

The logic 0 on control input 104 causes AND gate 320 in conjunction with inverter I4 to output a logic 1, disabling high impedance PFET 3P2. Similarly, the logic 0 on control input 104 causes NAND gate 324 in conjunction with inverter I7 to output a logic 0, disabling NFET 3N2. Thus, in resonant mode, high-impedance driver 307 remains disabled.

Dual-driver mode may be used for driving a resonant clock signal using impulses from both low-impedance and high-impedance FET drivers. Dual-driver mode may be used for driving clocks at a high frequency for IC functional operation, or at lower frequencies for testing and debug purposes.

The timing, duration and operation of the low-impedance drive impulses in dual-driver mode may be similar to that of resonant mode.

While operating in dual-driver mode, both control input 104 and clock control input 105 are held to a logic 1. The logic 1 on control input 104 causes AND gate 320 in conjunction with inverter I4 to output the complement of the reference clock input signal (on reference clock signal input 108), to the gate of PFET 3P2, turning it on during a rising phase of the clock signal output 110. Similarly, the logic 1 on control input 104 causes NAND gate 324 in conjunction with inverter I7 to output the complement of the reference clock input signal (on reference clock signal input 108) to the gate of NFET 3N2, turning it on during a falling phase of the clock signal output 110. Thus, in dual-driver mode, high-impedance driver 307 and high-impedance driver 318 are both simultaneously enabled to drive the clock signal output 110.

In dual-driver mode, both the high-impedance and low-impedance FETs may be turned on at the same time, effectively lowering the total impedance of sector clock buffer 312 below that of the low impedance driver. This may be particularly useful in allowing smaller FETs to be used in the construction of low impedance driver 318.

DC test mode may be used for driving a clock distribution signal using only the high-impedance FET driver 307. DC test mode may be used for driving clocks at low frequencies or in a DC single step mode, for IC testing and debug operations.

The timing, duration and operation of the high-impedance drive impulses in DC test mode may be similar to that of dual-driver mode.

While operating in DC test mode, control input 104 is held to a logic 1, and clock control input 105 is held to a logic 0. The logic 1 on control input 104 causes the gates of both PFET 3P2 and NFET 3N2 to be driven with the complement of the reference clock input signal (on reference clock signal input 108), thus driving the clock signal output 110 in a manner similar to dual-driver mode.

The logic 0 on control input 105 causes NAND gate 309 to block the reference clock input signal from the pulse generators 314, 316. Thus, in DC test mode only high-impedance driver 307 is enabled to drive the clock signal output 110.

Disabled mode may be used where circuitry other than sector clock buffer 312 controls the clock signal output 110, or where the clock signal output 110 is specified to remain in a tri-state mode. In disabled mode neither the high impedance driver 307 nor the low impedance driver 318 exerts any influence over clock signal output 110.

While operating in disabled mode, control inputs 104 and 105 are both held to a logic 0. The logic 0 on control input 104 causes PFET 3P2 and NFET 3N2 to both be disabled, similar to resonant mode. The logic 0 on control input 105 causes NAND gate 309 to block the reference clock input signal from the pulse generators 314, 316, thus disabling low-impedance FETs 3P1 and 3N1.

Thus, in disabled mode, both high-impedance driver 307, and low-impedance driver 318 are disabled.

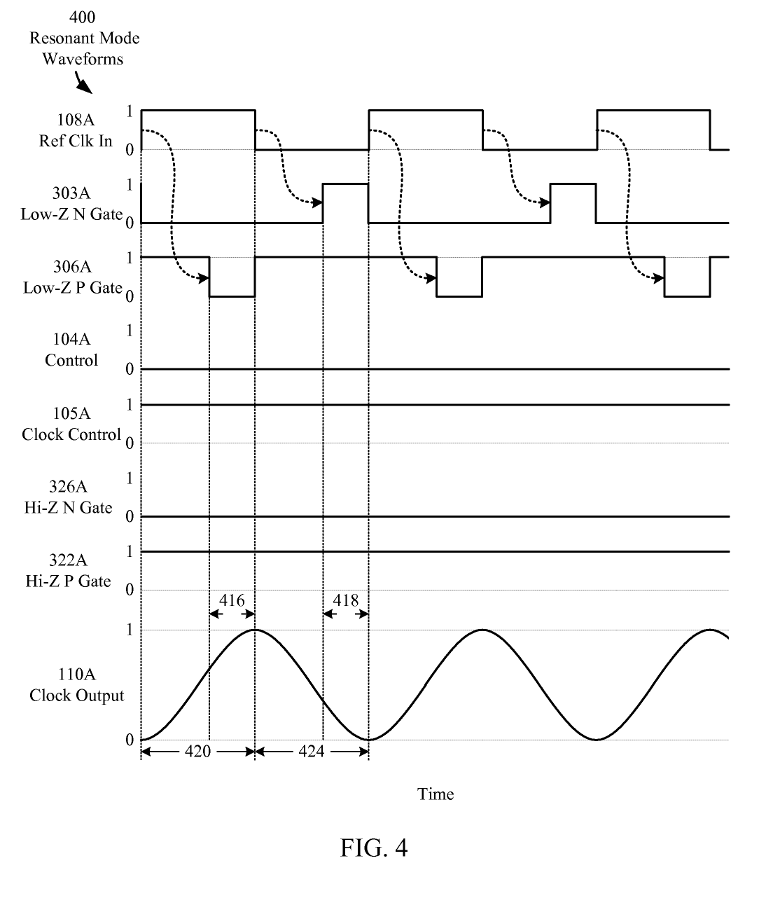

The schematic view of sector clock buffer 312 depicts one embodiment of the present disclosure. Other embodiments may use different numbers or configurations of logic circuits, inverters, buffers and transistors to affect the same control, functional and timing relationships that have been described, and which are further detailed in FIGS. 4, 5 and 6.

TABLE 1
Sector Clock Buffer Modes

| | Control Input | Clock Control Input |
|---|---|---|
| MODE | 104 | 105 |
| Resonant | 0 | 1 |
| Dual Driver | 1 | 1 |
| DC Test | 1 | 0 |
| Disabled | 0 | 0 |

FIG. 4 is a diagram of resonant mode waveforms 400 including reference clock input 108A, low impedance NFET gate 303A, low impedance PFET gate 306A, control input 104A, clock control input 105A, high impedance NFET gate 326A, high impedance PFET gate 322A, and clock output 110A, according to embodiments.

Resonant mode waveforms 400 depict the operation of sector clock buffer 312 in a resonant mode, driving clock output 110 (FIG. 3) to a resonant clock structure such as a clock grid (FIG. 2, 207). In resonant mode, control input 104A is held to a logic 0, clock control input 105A is held to a logic 1, and reference clock input 108A oscillates at a resonant frequency of a resonant clock distribution structure, such as a clock grid (FIG. 2, 207).

The low impedance NFET gate 303A and low impedance PFET gate 306A waveforms depict pulses generated by pulse generators 316, 314 (FIG. 3), respectively. Rising impulse time 416 and falling impulse time 418 depict intervals of rising phase 420 and falling phase 424, respectively of clock output 110A, during which impulses from sector clock buffer 312 add energy to the resonant clock signal.

The delay of impulse times 416, 418 from their respective triggering edges of reference clock input 108A may be modified, by specifying characteristics of pulse generators 314, 316 (FIG. 3), respectively. The width (duration) of impulse times 416, 418 may be similarly modified.

The clock output 110A waveform is divided into a rising phase 420 and a falling phase 424. A rising or falling impulse time (416, 418) may occur during a portion of each of these phases. Rising impulse time 416 may also be positioned at any location within rising phase 420, and falling impulse time 418 may similarly be positioned at any location within falling phase 424, in order to avoid contention between sector clock buffer 312 and the resonant clock distribution structure.

In embodiments, a rising or falling impulse time (416, 418) may be between 10% and 90% of a rising or falling phase (420, 424), depending on the amount of energy required to maintain the clock output 110A in a resonant state, the chip's power budget, pulse generator (314, 316) accuracy and repeatability, and other application requirements.

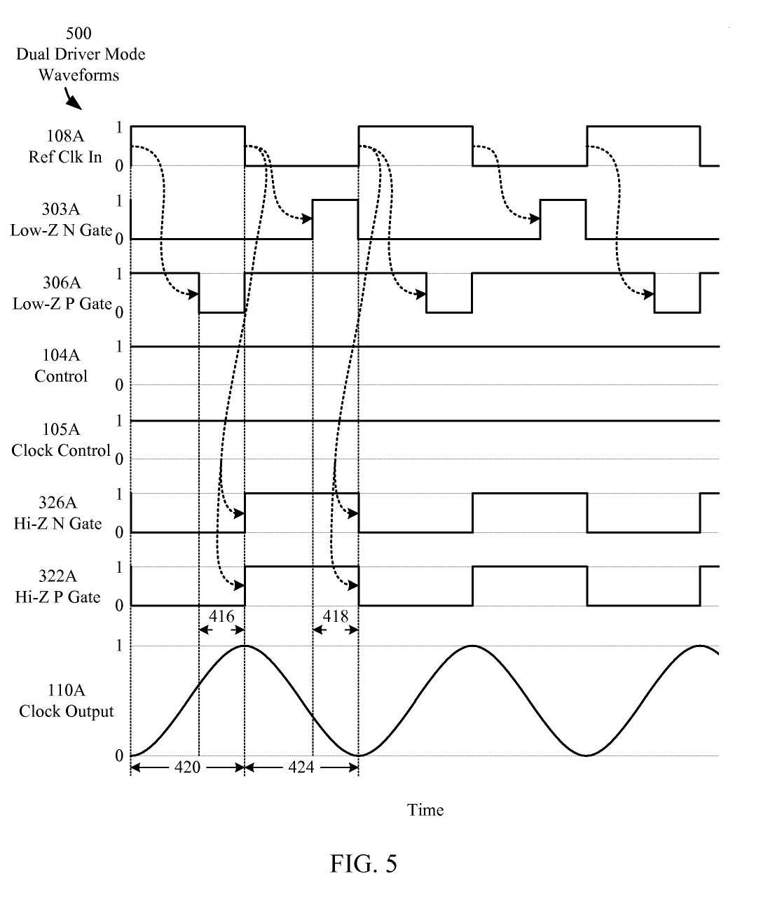

FIG. 5 is a diagram of dual driver mode waveforms 500 including reference clock input 108A, low impedance NFET gate 303A, low impedance PFET gate 306A, control input 104A, clock control input 105A, high impedance NFET gate 326A, high impedance PFET gate 322A, and clock output 110A, in an embodiment consistent with FIG. 4.

Dual driver mode waveforms 500 depict the operation of sector clock buffer 312 (FIG. 3) in a dual driver mode, driving clock output 110 (FIG. 3) to a resonant clock structure such as a clock grid (FIG. 2, 207). In dual driver mode, control inputs 104A and 105A are both held to a logic 1, and reference clock input 108A oscillates at a specified frequency.

Waveforms 322A and 326A depict the PFET and NFET gate inputs of high impedance driver 307 (FIG. 3), which are driven with the complement of reference clock input 108A. The low impedance NFET gate 303A and low impedance PFET gate 306A waveforms are generally similar to waveforms 303A, 306A.

The clock output 110A waveform is divided into a rising phase 420 and a falling phase 424. Impulse times 416, 418 have similar characteristics to, and may be modified and positioned similarly to impulse times 416, 418 (FIG. 4).

During rising phase 420, the high impedance PFET 3P2 (FIG. 3) is enabled, in order to pull up or hold clock output 110 (FIG. 3). During falling phase 424, the low impedance NFET 3N2 (FIG. 3) is enabled, in order to pull down or hold clock output 110A. At certain frequencies, the resonant nature of the clock grid (FIG. 2, 207), or other distribution structure may not generally support stable clock voltages. At these frequencies, the high impedance FETs of sector clock buffer 312 (FIG. 3) may be particularly useful in holding the clock output signal 110 at a voltage corresponding to a logic 0 or a logic 1.

An IC designed according to embodiments of the present disclosure may also be configured to provide compacted low-impedance FETS, due to the parallel use of high-impedance and low-impedance FETS in dual driver mode. The impedance of the high-impedance FETS may be 50 Ohms, and the impedance of the high-impedance FETS may be 10 Ohms in an embodiment, providing an effective impedance of 8.33 Ohms. If a low impedance FET of 8.33 Ohms is required, and no dual driver mode is available, the low impedance FET would have to be 20% wider.

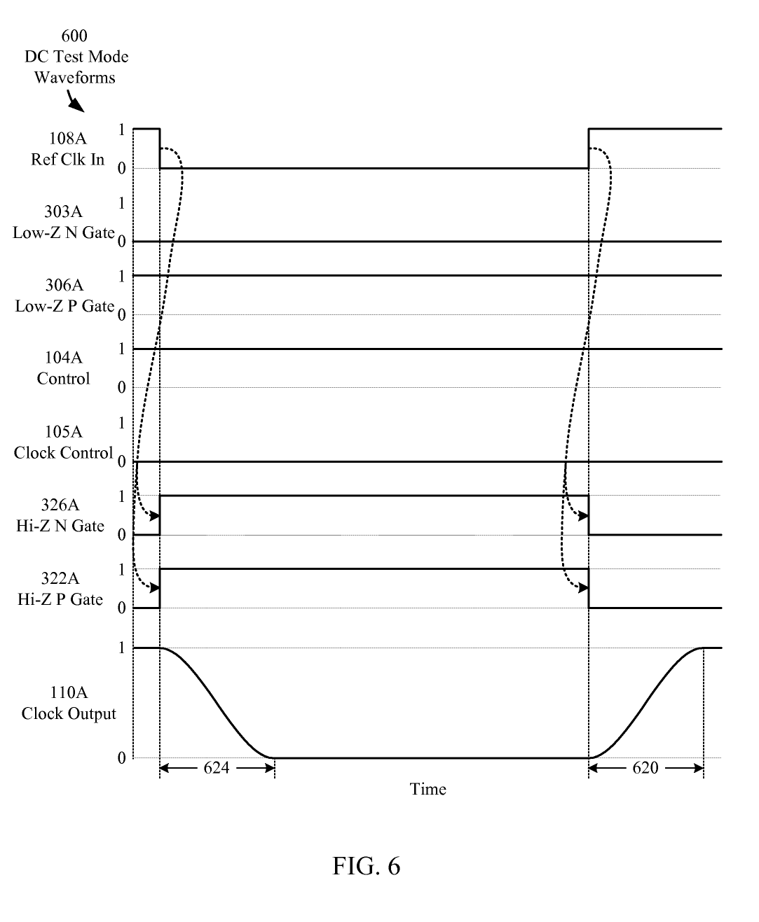

FIG. 6 is a diagram of DC test mode waveforms 600 including reference clock input 108A, low impedance NFET gate 303A, low impedance PFET gate 306A, control input 104A, clock control input 105A, high impedance NFET gate 326A, high impedance PFET gate 322A, and clock output 110A, according to embodiments.

DC test mode waveforms 600 depicts the operation of sector clock buffer 312 (FIG. 3) in a DC test mode, driving clock output 110 (FIG. 3) to a resonant clock structure such as a clock grid (FIG. 2, 207). In DC test mode, control inputs 104A is held to a logic 1, and 105A is held to a logic 0, and reference clock input 108A oscillates at a specified frequency.

Waveforms 322A and 326A depict the PFET and NFET gate inputs of high impedance driver 307 (FIG. 3), which are driven with the complement of reference clock input 108A. The low impedance NFET gate 303A and low impedance PFET gate 306A waveforms are indicative of the low impedance driver 318 being disabled by clock control input 105 being held to a logic 0.

The clock output 110A waveform depicts a falling phase 624 and a rising phase 620. During rising phase 620, the high impedance PFET 3P2 (FIG. 3) is enabled, in order to pull up or hold clock output 110A. During falling phase 624, the low impedance NFET 3N2 (FIG. 3) is enabled, in order to pull down or hold clock output 110A. At certain frequencies, the resonant nature of the clock grid (FIG. 2, 207), or other distribution structure may not generally support stable clock voltages. At these frequencies, the high impedance FETs of sector clock buffer 312 (FIG. 3) may be particularly useful in holding the clock output signal 110 at a voltage corresponding to a logic 0 or a logic 1. Rise and fall times 620, 624 depicted may be greater than rise and fall times 420, 424 (FIG. 4) due to the use of a higher impedance driver than is used pertaining to FIG. 4.

The impedance of the high-impedance FETS may be 50 Ohms, and the impedance of the high-impedance FETS may be 10 Ohms in an embodiment.

Although the present invention has been described in terms of specific embodiments, it is anticipated that alterations and modifications thereof may become apparent to those skilled in the art. Therefore, it is intended that the following claims be interpreted as covering all such alterations and modifications as fall within the true spirit and scope of the invention.

1. A system comprising:
an integrated circuit (IC), including:
a plurality of sectors each having:
a resonant clock distribution structure; and
at least one sector clock buffer, to receive a reference clock signal and a control signal, and to drive a clock signal onto the resonant clock distribution structure of the sector, in response to the reference clock signal, the sector clock buffer having:
a first driver circuit, with a first impedance, to drive the clock signal during a first portion of a first clock signal phase to a first voltage, and during a first portion of a second clock signal phase to a second voltage, to cause resonant oscillation of the resonant clock distribution structure; and
a second driver circuit, with a second impedance higher than the first impedance, to maintain the clock signal during a second portion of the first clock signal phase, and during a second portion of the second clock signal phase, in response to the control signal, to maintain the resonant clock distribution structure at one of the first and the second voltage.

2. The system of claim 1, wherein in response to the control signal, the second driver circuit to draw the clock signal to the first voltage during the entire first clock signal phase, and to the second voltage during the entire second clock signal phase, by maintaining the resonant clock distribution structure at the first voltage during the second portion of the first clock signal phase, and at the second voltage during the second portion of the second clock signal phase.

3. The system of claim 1, wherein in response to a clock control signal, the first driver circuit is disabled.

4. The system of claim 1, wherein the sector clock buffers have a variable input loading.

5. The system of claim 1, wherein the reference clock input is coupled to a clock input network.

6. The system of claim 5, wherein the clock input network comprises an H-tree structure.

7. The system of claim 1, wherein the resonant clock distribution structure of the sector is a grid.

8. The system of claim 7, further comprising an inductor formed in the grid to cause it to resonate at a specified clock frequency.

9. The system of claim 8, wherein the inductor formed in the grid is a spiral inductor.

10. The system of claim 1, wherein the resonant clock distribution structure of the sector is electrically coupled to the resonant clock distribution structure of an adjacent sector.
